(19) United States
(12) Patent Application Publication
(10) Pub. No.: US 2026/0128070 A1
(43) Pub. Date: May 7, 2026

(54) MEMORY APPARATUS

(71) Applicant: SK hynix Inc., Gyeonggi-do (KR)

(72) Inventors: Jong Hyuck CHOI, Gyeonggi-do (KR); Sang Sic YOON, Gyeonggi-do (KR); Hyung Rok DO, Gyeonggi-do (KR); Jeong Je PARK, Gyeonggi-do (KR); Joon Hong PARK, Gyeonggi-do (KR)

(21) Appl. No.: 19/078,300

(22) Filed: Mar. 13, 2025

(30) Foreign Application Priority Data
Nov. 4, 2024 (KR) 10-2024-0154294

(51) Int. Cl. G11C 8/18

(52) U.S. Cl. CPC G11C 8/18

(57) ABSTRACT

A memory apparatus includes a domain crossing circuit including a plurality of first flip-flops operating based on the internal clock and a plurality of second flip-flops operating based on a data clock, the plurality of first flip-flops being initialized by the system domain reset signal, the plurality of second flip-flops being initialized by the data domain reset signal.

### CROSS-REFERENCE TO RELATED APPLICATION

This application claims priority under 35 U.S.C. § 119(a) to Korean Patent Application No. 10-2024-0154294 filed on Nov. 4, 2024, which is incorporated herein by reference in its entirety.

### BACKGROUND

### 1. Technical Field

Embodiments of the present disclosure relate to an integrated circuit technology, and more particularly, to a memory apparatus.

### 2. Related Art

Recently, with the miniaturization, low power consumption, high performance, diversification, and the like of electronic devices, there is a demand for memory apparatuses capable of storing information in various electronic devices such as computers and portable communication devices.

In order to implement high performance, a memory apparatus that inputs and outputs data at a high speed is being developed to use a system clock for receiving addresses and commands and a data clock for inputting and outputting data. In this way, the memory apparatus using heterogeneous clocks requires a domain crossing circuit that can synchronize the heterogeneous clocks. For example, a domain crossing circuit that synchronizes a command synchronized to the system clock to the data clock is required.

### SUMMARY

In an embodiment of the present disclosure, a memory apparatus includes a timing control circuit that outputs a system domain reset signal and a data domain reset signal based on a system clock, and outputs the system clock as an internal clock when the system domain reset signal is output, an output timing of the system domain reset signal being different from an output timing of the data domain reset signal; and a domain crossing circuit including a plurality of first flip-flops operating based on the internal clock and a plurality of second flip-flops operating based on a data clock, the plurality of first flip-flops being initialized by the system domain reset signal, the plurality of second flip-flops being initialized by the data domain reset signal.

In an embodiment of the present disclosure, a memory apparatus includes a command decoding circuit that outputs a read/write command and a CAS command synchronized to a system clock; a timing control circuit that outputs a system domain reset signal, a data domain reset signal, and an internal clock based on the CAS command and the system clock, and outputs a delayed read/write command based on the system clock and the read/write command; and a domain crossing circuit that synchronizes the delayed read/write command with a data clock and outputs a data input/output command under control of the system domain reset signal, the data domain reset signal, and the internal clock.

### BRIEF DESCRIPTION OF THE DRAWINGS

FIG. 1 is a diagram for describing the configuration of a memory apparatus in accordance with an embodiment of the present disclosure.

FIG. 2 is a diagram for describing the configuration of a timing control circuit included in the memory apparatus in accordance with an embodiment of the present disclosure.

FIG. 3 is a diagram for describing the configuration of a domain crossing circuit included in the memory apparatus in accordance with an embodiment of the present disclosure.

FIG. 4 is a timing diagram for describing the operation of the memory apparatus in accordance with an embodiment of the present disclosure.

FIG. 5 is a diagram for describing the configuration of a memory apparatus in accordance with another embodiment of the present disclosure.

FIG. 6 is a diagram for describing the configuration of a timing control circuit included in the memory apparatus in accordance with another embodiment of the present disclosure.

FIG. 7 is a diagram for describing the configuration of a domain crossing circuit included in the memory apparatus in accordance with another embodiment of the present disclosure.

FIG. 8 is a timing diagram for describing the operation of the memory apparatus in accordance with another embodiment of the present disclosure.

### DETAILED DESCRIPTION

Various embodiments of the present disclosure are directed to a memory apparatus that provides a system clock to a domain crossing circuit at an earlier timing compared to a data clock.

The operation reliability of a memory apparatus can be improved.

Hereafter, embodiments in accordance with the technical spirit of the present disclosure are described with reference to the accompanying drawings.

A memory apparatus is configured to store data and output the stored data. For example, the memory apparatus receives a command for storing data received from an external device (for example, a memory controller) or outputting the stored data, and receives data from the external device or outputs the stored data to the external device. In such a case, the memory apparatus receives a command in synchronization with a system clock and outputs the stored data in synchronization with a data clock. Accordingly, the memory apparatus includes a domain crossing circuit for the system clock and the data clock.

It is noted that the following description relates to a domain crossing circuit included in a memory apparatus using heterogeneous clocks, describes a domain crossing circuit for a system clock and a data clock as an example of the heterogeneous clocks, and does not limit only the system clock and the data clock.

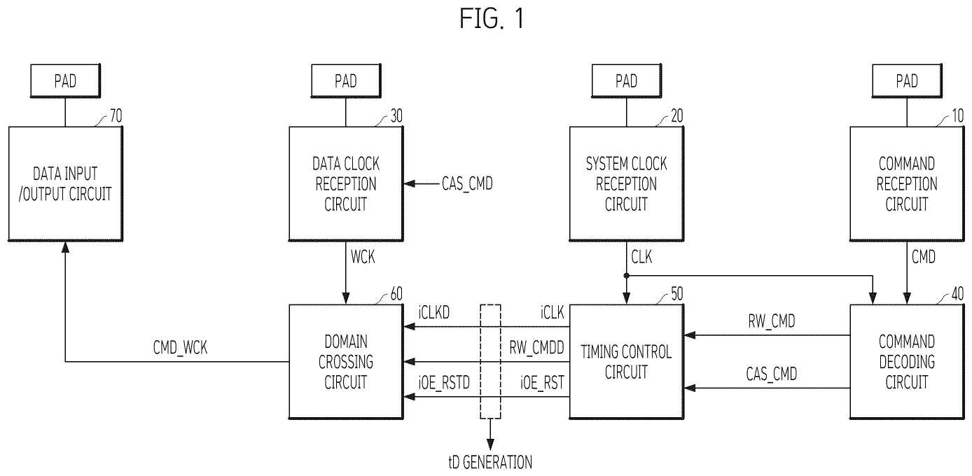

FIG. 1 is a diagram for describing the configuration of a memory apparatus in accordance with an embodiment of the present disclosure.

Referring to FIG. 1, the memory apparatus includes a command reception circuit 10, a system clock reception circuit 20, a data clock reception circuit 30, a command decoding circuit 40, a timing control circuit 50, a domain crossing circuit 60, and a data input and output (input/output) circuit 70.

In an embodiment, the command reception circuit 10 receives a signal for controlling the operation of the memory apparatus from an external device (for example, a memory controller) through a pad PAD, and outputs the signal as a command signal CMD. The signal provided to the command reception circuit 10 from the external device is a single-ended signal or a differential-mode signal. The command signal CMD output from the command reception circuit 10 is provided to the command decoding circuit 40.

In an embodiment, the system clock reception circuit 20 receives, from the external device through a pad PAD, a signal for synchronizing the operation of the memory apparatus to the operation of the external device (for example, a memory controller), and outputs the signal as a system clock CLK. The signal provided to the system clock reception circuit 20 from the external device is a single-ended signal or a differential-mode signal. The system clock CLK output from the system clock reception circuit 20 is provided to the command decoding circuit 40 and the timing control circuit 50.

In an embodiment, the data clock reception circuit 30 is activated or deactivated based on a column address strobe (CAS) command CAS_CMD. The activated data clock reception circuit 30 receives, from the external device through a pad PAD, a signal for synchronizing a data input/output timing of the memory apparatus to a data input/output timing of the external device (for example, a memory controller), and outputs the signal as a data clock WCK. The signal provided to the data clock reception circuit 30 from the external device is a single-ended signal or a differential-mode signal. The data clock CLK output from the data clock reception circuit 30 is provided to the domain crossing circuit 60.

In an embodiment, each of the command reception circuit 10, the system clock reception circuit 20, and the data clock reception circuit 30 includes a buffer.

In an embodiment, the command decoding circuit 40 receives the command signal CMD from the command reception circuit 10, and receives the system clock CLK from the system clock reception circuit 20. The command decoding circuit 40 decodes the command signal CMD in synchronization with the system clock CLK. The command decoding circuit 40 outputs a read/write command RW_CMD and the CAS command CAS_CMD as a decoding result. The command decoding circuit 40 also provides the read/write command RW_CMD and the CAS command CAS_CMD to the timing control circuit 50. The command decoding circuit 40 provides the CAS command CAS_CMD to the data clock reception circuit 30. The read/write command RW_CMD is a command generated when the external device instructs an operation (for example, a read operation) of the memory apparatus to output data stored in the memory apparatus or an operation (for example, a write operation) of the memory apparatus to store data transmitted to the memory apparatus. The CAS command CAS_CMD is a command generated when the external device instructs the activation of the data clock reception circuit 30.

In an embodiment, the timing control circuit 50 receives the system clock CLK from the system clock reception circuit 20 and receives the read/write command RW_CMD and the CAS command CAS_CMD from the command decoding circuit 40. The timing control circuit 50 delays each of the system clock CLK, the read/write command RW_CMD, and the CAS command CAS_CMD by a set delay time, and outputs the delayed clock and command. The timing control circuit 50 may set the delay time by using one cycle of the system clock CLK as a unit delay time.

For example, the timing control circuit 50 sets two cycles of the system clock CLK as a delay time, delays an input signal by the two cycles of the system clock CLK, and outputs the delayed signal. More specifically, for example, when the CAS command CAS_CMD is received from the command decoding circuit 40, the timing control circuit 50 delays the CAS command CAS_CMD by the two cycles of the system clock CLK and outputs the delayed command as a domain crossing reset signal iOE_RST. In addition, when the system clock CLK is received from the system clock reception circuit 20, the timing control circuit 50 outputs the system clock CLK as an internal clock iCLK after the delay time (two cycles of the system clock CLK). The timing control circuit 50 outputs, as the internal clock iCLK, the system clock CLK at the timing at which the domain crossing reset signal iOE_RST is output when the delay times of the system clock CLK and the CAS command CAS_CMD are the same. In some embodiments, the delay time of the read/write command RW_CMD is set in consideration of a latency, an asynchronous delay time inside the memory apparatus, an operation time of the domain crossing circuit 60, and the like. For example, when the latency is set so that stored data is output when 10 cycles of the system clock CLK elapse after a read command is received, the asynchronous delay time corresponds to one cycle of the system clock CLK, and the operation time of the domain crossing circuit 60 corresponds to three cycles of the system clock CLK, the memory apparatus sets the delay time of the read/write command RW_CMD to a time corresponding to six cycles of the system clock CLK. In such a case, when the read/write command RW_CMD is received from the command decoding circuit 40, the timing control circuit 50 delays the read/write command RW_CMD by six cycles of the system clock CLK and outputs the delayed command as a delayed read/write command RW_CMDD.

In addition, the internal clock iCLK, the delayed read/write command RW_CMDD, and the domain crossing reset signal iOE_RST transmitted from the timing control circuit 50 to the domain crossing circuit 60 is further delayed by a time (for example, asynchronous delay time tD) transmitted from the timing control circuit 50 to the domain crossing circuit 60. Signals received in the domain crossing circuit 60, including the asynchronous delay time, are denoted as iCLKD and iOE_RSTD, and are described as a delayed internal clock iCLKD and a delayed domain crossing reset signal IOE_RSTD, respectively.

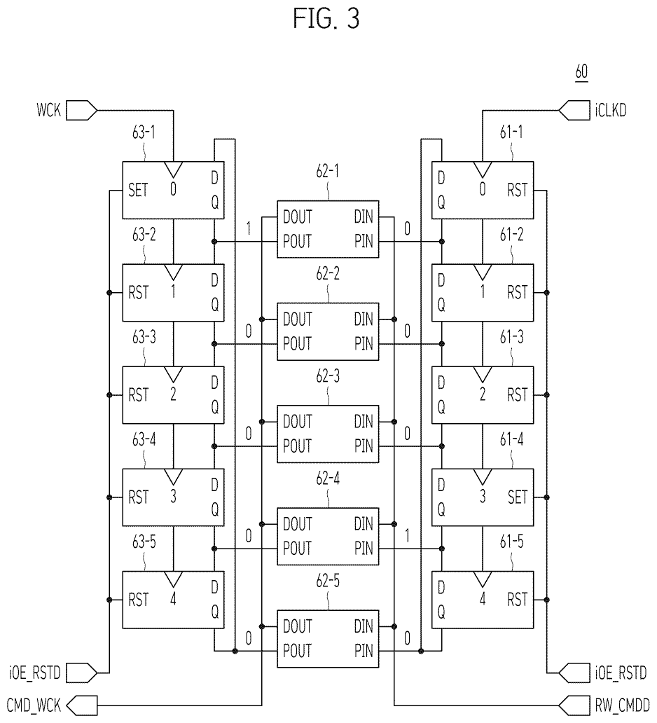

In an embodiment, the domain crossing circuit 60 receives the data clock WCK from the data clock reception circuit 30, and receives the internal clock iCLK, the delayed read/write command RW_CMDD, and the domain crossing reset signal iOE_RST transmitted from the timing control circuit 50. The domain crossing circuit 60 converts a signal synchronized to the system clock CLK into a signal synchronized to the data clock WCK and outputs the converted signal. Accordingly, the domain crossing circuit 60 converts the delayed read/write command RW_CMDD synchronized to the system clock WCK into a data input/output command CMD_WCK synchronized to the data clock WCK and outputs the data input/output command CMD_WCK under the control of the data clock WCK, the internal clock iCLK based on the system clock WCK, and the domain crossing reset signal iOE_RST. The operation of the domain crossing circuit 60 is described in detail with reference to FIG. 3.

In an embodiment, the data input/output circuit 70 is activated when the data input/output command CMD_WCK is received, and outputs data to the external device or receives data from the external device through a pad PAD.

As described above, the memory apparatus includes the domain crossing circuit 60 that converts a signal (for example, the read/write command RW_CMD) synchronized to the system clock CLK into a signal (for example, the data input/output command CMD_WCK) synchronized to the data clock WCK. The read/write command RW_CMD synchronized to the system clock CLK and the data input/output command CMD_WCK synchronized to the data clock WCK are merely described as examples, and the embodiments of the present disclosure are not limited thereto.

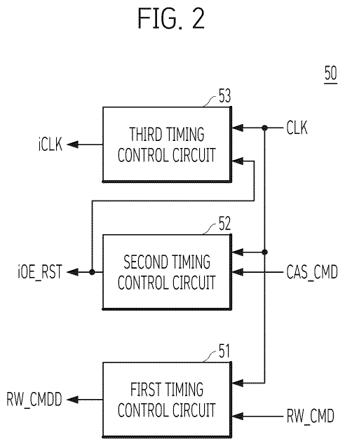

FIG. 2 is a diagram for describing the configuration of the timing control circuit 50 included in the memory apparatus in accordance with an embodiment of the present disclosure.

Referring to FIG. 2, the timing control circuit 50 includes a plurality of timing control circuits 51 to 53. For example, the timing control circuit 50 includes first to third timing control circuits 51 to 53 which control (e.g., delay) output timings of the read/write command RW_CMD, the CAS command CAS_CMD, and the system clock CLK by set delay times and output the delayed commands and clock.

In an embodiment, the first timing control circuit 51 receives the read/write command RW_CMD and the system clock CLK and outputs the delayed read/write command RW_CMDD. For example, the first timing control circuit 51 delays the read/write command RW_CMD by a set delay time (for example, six cycles of the system clock CLK), and outputs the delayed command as the delayed read/write command RW_CMDD. That is, the first timing control circuit 51 outputs the delayed read/write command RW_CMDD at the timing at which the six cycles of the system clock CLK elapse from the timing at which the read/write command RW_CMD is received.

In an embodiment, the second timing control circuit 52 receives the CAS command CAS_CMD and the system clock CLK and outputs the domain crossing reset signal iOE_RST. For example, the second timing control circuit 52 delays the CAS command CAS_CMD by a set delay time (for example, two cycles of the system clock CLK) and outputs the delayed command as the domain crossing reset signal iOE_RST. That is, the second timing control circuit 52 outputs the domain crossing reset signal iOE_RST at the timing at which the two cycles of the system clock CLK elapse from the timing at which the CAS command CAS_CMD is received.

In an embodiment, the third timing control circuit 53 receives the system clock CLK and the domain crossing reset signal iOE_RST and outputs the internal clock iCLK. For example, the third timing control circuit 53 outputs the system clock CLK as the internal clock iCLK when a set delay time (for example, two cycles of the system clock CLK) elapses after the CAS command CAS_CMD is received. That is, the third timing control circuit 53 outputs the system clock CLK as the internal clock iCLK at the timing at which the two cycles of the system clock CLK elapses from the timing at which the CAS command CAS_CMD is received.

Each of the first to third timing control circuits 51 to 53 includes a shift register in which a plurality of flip-flops is connected in series. Unlike the first and second timing control circuits 51 and 52, the third timing control circuit 53 includes a flip-flop and an AND gate. The flip-flop may output a high-level signal when the domain crossing reset signal iOE_RST is received. The AND gate may receive the output of the flip-flop and the system clock CLK and perform an AND operation on the received signal and clock.

FIG. 3 is a diagram for describing the configuration of the domain crossing circuit 60 included in the memory apparatus in accordance with an embodiment of the present disclosure.

In an embodiment, the domain crossing circuit 60 includes a plurality of flip-flops operating based on the system clock CLK, a plurality of pipe circuits, and a plurality of flip-flops operating based on the data clock WCK. Each flip-flop includes a D flip-flop.

In FIG. 3, the domain crossing circuit 60 includes first to fifth flip-flops 61-1 to 61-5 operating based on the system clock CLK, first to fifth pipe circuits 62-1 to 62-5, and first to fifth flip-flops 63-1 to 63-5 operating based on the data clock WCK. The domain crossing circuit 60 illustrated in FIG. 3 is merely an example including the five flip-flops 61-1 to 61-5 operating based on the system clock CLK, the five pipe circuits 62-1 to 62-5, and the five flip-flops 63-1 to 63-5 operating based on the data clock WCK, and the number of flip-flops and the number of pipe circuits are not limited. In addition, each of the plurality of flip-flops 61-1 to 61-5 operates by receiving the delayed internal clock iCLKD, but the delayed internal clock iCLKD is also generated based on the system clock CLK. Accordingly, it can be described that the plurality of flip-flops 61-1 to 61-5 operate based on the system clock CLK.

In an embodiment, each of the first to fifth flip-flops 61-1 to 61-5 operating based on the system clock CLK receives the delayed internal clock CLKD. In addition, an input/output structure of the first to fifth flip-flops 61-1 to 61-5 operating based on the system clock CLK is a ring structure. For example, an output of the first flip-flop 61-1 is provided as an input of the second flip-flop 61-2, an output of the second flip-flop 61-2 is provided as an input of the third flip-flop 61-3, an output of the third flip-flop 61-3 is provided as an input of the fourth flip-flop 61-4, an output of the fourth flip-flop 61-4 is provided as an input of the fifth flip-flop 61-5, and an output of the fifth flip-flop 61-5 is provided as an input of the first flip-flop 61-1. In addition, one of the first to fifth flip-flops 61-1 to 61-5 receives the delayed domain crossing reset signal iOE_RSTD through a set terminal SET thereof, and the remaining flip-flops receive the delayed domain crossing reset signal iOE_RSTD through reset terminals RST thereof. In FIG. 3, among the first to fifth flip-flops 61-1 to 61-5, the fourth flip-flop 61-4 receives the delayed domain crossing reset signal iOE_RSTD through the set terminal SET thereof, and the remaining flip-flops 61-1, 61-2, 61-3, and 61-5 receive the delayed domain crossing reset signal iOE_RSTD through the reset terminals RST thereof. When the delayed domain crossing reset signal iOE_RSTD is received in the first to fifth flip-flops 61-1 to 61-5, the fourth flip-flop 61-4 outputs a signal at a first level (for example, high level of 1), and the remaining flip-flops 61-1, 61-2, 61-3, and 61-5 output a signal at a second level (for example, low level of 0).

In an embodiment, the first to fifth flip-flops 61-1 to 61-5 configured in this manner and operating based on the system clock CLK provide the output of a previous flip-flop as the input of a next flip-flop whenever the delayed internal clock iCLKD transitions to a specific level. For example, whenever the delayed internal clock iCLKD transitions to the specific level, the output of the fourth flip-flop 61-4, which is at the first level, is provided as the input of the fifth flip-flop 61-5, the output of the fifth flip-flop 61-5 is provided as the input of the first flip-flop 61-1, the output of the first flip-flop 61-1 is provided as the input of the second flip-flop 61-2, the output of the second flip-flop 61-2 is provided as the input of the third flip-flop 61-3, and the output of the third flip-flop 61-3 is provided again as the input to the fourth flip-flop 61-4. In such a case, each of the first to fifth flip-flops 61-1 to 61-5 may store the level of a signal input at the timing at which the delayed internal clock iCLKD transitions to the specific level, and may output the stored signal. Accordingly, whenever the delayed internal clock iCLKD transitions to the specific level, each of the outputs of the first to fifth flip-flops 61-1 to 61-5 operating based on the system clock CLK is output by circulating the first level being the output of the fourth flip-flop 61-4.

In an embodiment, each of the first to fifth pipe circuits 62-1 to 62-5 receives the delayed read/write command RW_CMDD through an input terminal DIN thereof. In addition, the first to fifth pipe circuits 62-1 to 62-5 receive the outputs of the first to fifth flip-flops 61-1 to 61-5 operating based on a system clock CLK through input control terminals PIN thereof, respectively. For example, the input control terminal PIN of the first pipe circuit 62-1 receives the output of the first flip-flop 61-1. The input control terminal PIN of the second pipe circuit 62-2 receives the output of the second flip-flop 61-2. The input control terminal PIN of the third pipe circuit 62-3 receives the output of the third flip-flop 61-3. The input control terminal PIN of the fourth pipe circuit 62-4 receives the output of the fourth flip-flop 61-4. The input control terminal PIN of the fifth pipe circuit 62-5 receives the output of the fifth flip-flop 61-5.

In an embodiment, when a signal of the first level (e.g., 1) is received through the input control terminal PIN, each of the first to fifth pipe circuits 62-1 to 62-5 configured in this manner receives and stores the delayed read/write command RW_CMDD provided to the input terminal DIN.

For example, whenever the delayed internal clock iCLKD transitions to the specific level, the output of each of the first to fifth flip-flops 61-1 to 61-5 operating based on the system clock CLK circulates the first level being the output of the fourth flip-flop 61-4. The outputs of the first to fifth flip-flops 61-1 to 61-5 are provided to the input control terminals PINs of the first to fifth pipe circuits 62-1 to 62-5, respectively. Therefore, the first level circulating along the first to fifth flip-flops 61-1 to 61-5 is controlled so that only one of the first to fifth pipe circuits 62-1 to 62-5 receives and stores the delayed read/write command RW_CMDD. In addition, a pipe circuit that receives and stores the delayed read/write command RW_CMDD is also circulated in the order of the fourth pipe circuit 62-4, the fifth pipe circuit 62-5, the first pipe circuit 62-1, the second pipe circuit 62-2, and the third pipe circuit 62-3.

In an embodiment, each of the first to fifth flip-flops 63-1 to 63-5 operating based on the data clock WCK receives the delayed data clock WCK. In addition, the input/output structure of the first to fifth flip-flops 63-1 to 63-5 operating based on the data clock CLK is a ring structure. For example, an output of the first flip-flop 63-1 is provided as an input of the second flip-flop 63-2, an output of the second flip-flop 63-2 is provided as an input of the third flip-flop 63-3, an output of the third flip-flop 63-3 is provided as an input of the fourth flip-flop 63-4, an output of the fourth flip-flop 63-4 is provided as an input of the fifth flip-flop 63-5, and an output of the fifth flip-flop 63-5 is provided as an input of the first flip-flop 63-1. One of the first to fifth flip-flops 63-1 to 63-5 receives the delayed domain crossing reset signal iOE_RSTD through a set terminal SET thereof, and the remaining flip-flops receive the delayed domain crossing reset signal IOE_RSTD through reset terminals RST thereof. In FIG. 3, among the first to fifth flip-flops 63-1 to 63-5, the first flip-flop 63-1 receives the delayed domain crossing reset signal iOE_RSTD through the set terminal SET thereof, and the remaining flip-flops 63-2, 63-3, 63-4, and 63-5 receive the delayed domain crossing reset signal iOE_RSTD through the reset terminals RST thereof. When the delayed domain cross reset signal iOE_RSTD is received in the first to fifth flip-flops 63-1 to 63-5, the first flip-flop 63-1 outputs a signal at the first level (for example, high level of 1), and the remaining flip-flops 63-2, 63-3, 63-4, and 63-5 output a signal at the second level (for example, low level of 0).

In an embodiment, the first to fifth flip-flops 63-1 to 63-5 configured in this manner and operating based on the data clock CLK provide the output of a previous flip-flop as the input of a next flip-flop whenever the data clock WCK transitions to a specific level. For example, whenever the data clock WCK transitions to the specific level, the output of the first flip-flop 63-1, which is at the first level, is provided as the input of the second flip-flop 63-2, the output of the second flip-flop 63-2 is provided as the input of the third flip-flop 63-3, the output of the third flip-flop 63-3 is provided as the input of the fourth flip-flop 63-4, the output of the fourth flip-flop 63-4 is provided as the input of the fifth flip-flop 63-5, and the output of the fifth flip-flop 63-5 is provided again as the input of the first flip-flop 63-1. In such a case, each of the first to fifth flip-flops 63-1 to 63-5 is configured to store the level of a signal input when the data clock WCK transitions to the specific level, and outputs the stored signal. Accordingly, whenever the data clock WCK transitions to the specific level, each of the outputs of the first to fifth flip-flops 63-1 to 63-5 circulates and outputs the first level being the output of the first flip-flop 63-1.

In an embodiment, the first to fifth pipe circuits 62-1 to 62-5 receive the outputs of the first to fifth flip-flops 63-1 to 63-5 operating based on the data clock WCK through output control terminals POUT thereof. In addition, output terminals DOUT of the first to fifth pipe circuits 62-1 to 62-5 are commonly connected, and the data input/output command CMD_WCK is output from a node to which the output terminals DOUT are commonly connected.

For example, the output control terminal POUT of the first pipe circuit 62-1 receives the output of the first flip-flop 63-1. The output control terminal POUT of the second pipe circuit 62-2 receives the output of the second flip-flop 63-2. The output control terminal POUT of the third pipe circuit 62-3 receives the output of the third flip-flop 63-3. The output control terminal POUT of the fourth pipe circuit 62-4 receives the output of the fourth flip-flop 63-4. The output control terminal POUT of the fifth pipe circuit 62-5 receives the output of the fifth flip-flop 63-5.

Accordingly, when a signal of the first level (e.g., 1) is received through the output control terminal POUT, each of the first to fifth pipe circuits 62-1 to 62-5 outputs the data input/output command CMD_WCK to the output terminal DOUT.

The operations of the first to fifth flip-flops 63-1 to 63-5 operating based on the data clock WCK and the first to fifth pipe circuits 62-1 to 62-5 are described, for example, as follows.

In an embodiment, each of the outputs of the first to fifth flip-flops 63-1 to 63-5 operating whenever the data clock WCK transitions to the specific level circulates the first level being the output of the first flip-flop 63-1. Accordingly, the first level circulating along the first to fifth flip-flops 63-1 to 63-5 controls only one of the first to fifth pipe circuits 62-1 to 62-5 to output the data input/output command CMD_WCK. In addition, a pipe circuit that outputs the data input/output command CMD_WCK is also circulated in the order of the first pipe circuit 62-1, the second pipe circuit 62-2, the third pipe circuit 62-3, the fourth pipe circuit 62-4, and the fifth pipe circuit 62-5.

In an embodiment, in a case in which the delayed domain crossing reset signal iOE_RSTD is input to the set terminal SET of the fourth flip-flop 61-4 among the first to fifth flip-flops 61-1 to 61-5 based on the system clock CLK and the set terminal SET of the first flip-flop 63-1 among the first to fifth flip-flops 63-1 to 63-5 based on the data clock WCK, when three cycles of the data clock WCK elapse from the timing at which the delayed read/write command RW_CMDD is stored in one of the first to fifth pipe circuits 62-1 to 62-5, the domain crossing circuit 60 configured in this manner outputs the data input/output command CMD_WCK. In addition, in order for the domain crossing circuit 60 to operate normally, a pipe operation time (tD_pipe, for example, three cycles of the system clock CLK) is required to allow the delayed read/write command RW_CMDD to be normally input to the first to fifth pipe circuits 62-1 to 62-5 after the delayed internal clock iCLKD is received in the first to fifth flip-flops 61-1 to 61-5 based on the system clock CLK.

The memory apparatus configured as illustrated in FIGS. 1 to 3 can operate as follows.

For example, signals for allowing the memory apparatus to perform a read operation are received from the external device.

In an embodiment, the command reception circuit 10 receives a signal from the external device and outputs the command signal CMD.

In an embodiment, the command decoding circuit 40 decodes the command signal CMD to generate the CAS command CAS_CMD and the read/write command RW_CMD. The CAS command CAS_CMD is input to the data clock reception circuit 30 to activate the data clock reception circuit 30. The CAS command CAS_CMD and the read/write command RW_CMD are provided to the timing control circuit 50 together with the system clock CLK.

In an embodiment, the timing control circuit 50 provides the domain crossing reset signal iOE_RST and the internal clock iCLK to the domain crossing circuit 60 when two cycles of the system clock CLK elapse after the CAS command CAS_CMD is received. In such a case, the domain crossing reset signal iOE_RST and the internal clock iCLK are delayed (iCLKD and iOE_RSTD) by the asynchronous delay time tD and are received in the domain crossing circuit 60. In addition, when four cycles of the system clock CLK elapse after the read/write command RW_CMD is received, the timing control circuit 50 provides the delayed read/write command RW_CMDD to the domain crossing circuit 60.

When the delayed domain crossing reset signal iOE_RSTD is received in the domain crossing circuit 60, the first to fifth flip-flops 61-1 to 61-5 operating based on the system clock CLK and the first to fifth flip-flops 63-1 to 63-5 operating based on the data clock WCK are initialized. The initialization operation of the flip-flops 61-1 to 61-5 and 63-1 to 63-5 includes determining a flip-flop outputting the first level by the delayed domain crossing reset signal iOE_RSTD input to the set terminal SET and the reset terminal RST.

Subsequently, the domain crossing circuit 60 receives and stores the delayed read/write command RW_CMDD in synchronization with the delayed internal clock iCKD. Subsequently, when three cycles of the data clock WCK elapse, the domain crossing circuit 60 provides, as the data input/output command CMD_WCK, the stored read/write command RW_CMDD to the data input/output circuit 70.

In this way, the domain crossing circuit 60 converts the read/write command RW_CMD based on the system clock CLK into the data input/output command CMD_WCK based on the data clock WCL.

However, the domain crossing circuit 60 needs to output the data input/output command CMD_WCK when three cycles of the data clock WCK elapse after the read/write command RW_CMD synchronized to the system clock CLK is input, but when the first to fifth flip-flops 63-1 to 63-5 operating based on the data clock WCK operate before the first to fifth flip-flops 61-1 to 61-5 operating based on the system clock CLK, an abnormal operation occurs in which the data input/output command CMD_WCK is output at an earlier timing than three cycles of the data clock WCK.

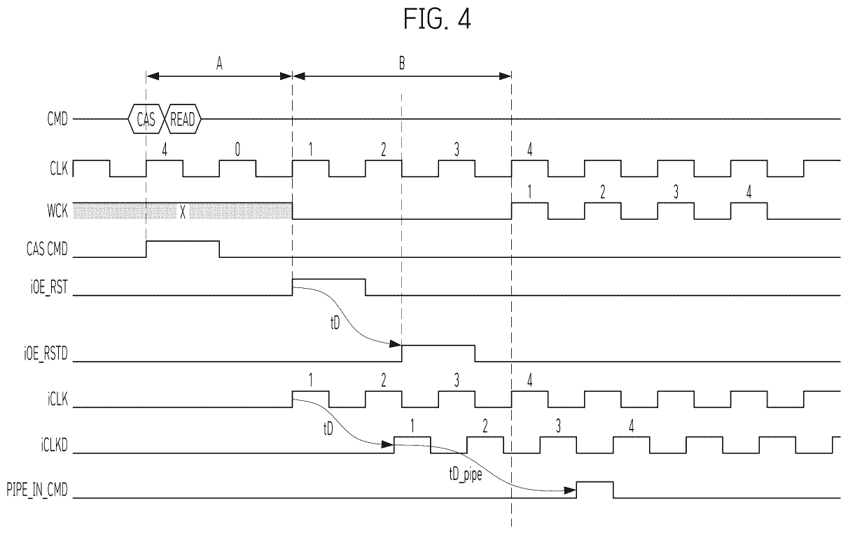

An abnormal operation of the domain crossing circuit 60 is described with reference to FIG. 4 as follows.

FIG. 4 is a timing diagram for describing the operation of the memory apparatus in accordance with an embodiment of the present disclosure. The read operation of the memory apparatus is described as an example.

Referring to FIG. 4, a signal for controlling the read operation of the memory apparatus is received in the memory apparatus from the external device. The signal for controlling the read operation includes a signal CAS for generating the CAS command CAS_CMD and a signal for generating the read/write command RW_CMD.

In an embodiment, the command decoding circuit 40 decodes signals provided from the command reception circuit 10 and generates the CAS command CAS_CMD and the read/write command RW_CMD. The CAS command CAS_CMD activates the data clock reception circuit 30. A line transmitting the data clock WCK is maintained in a floating state X from the timing at which the CAS command CAS_CMD is generated to the timing at which two cycles of the system clock CLK elapse. Subsequently, the data clock WCK is fixed to a set level (for example, a low level) until three cycles of the system clock CLK elapse. The data clock WCK is toggled after the three cycles of the system clock CLK elapse. For the convenience of description, a period where the line transmitting the data clock WCK is floated is called a period A, and a period where the data clock WCK is fixed to the set level is called a period B.

In an embodiment, the timing control circuit 50 generates the domain crossing reset signal iOE_RST by delaying the CAS command CAS_CMD by two cycles of the system clock CLK. In addition, the timing control circuit 50 outputs the system clock CLK as the internal clock iCLK when the domain crossing reset signal iOE_RST is generated. Accordingly, the generation timing of the domain crossing reset signal iOE_RST and the generation timing of the internal clock iCLK are the same.

In an embodiment, the domain crossing reset signal iOE_RST and the internal clock iCLK are delayed by the asynchronous delay time tD corresponding to loading according to the distance between the timing control circuit 50 and the domain crossing circuit 60, and are received in the domain crossing circuit 60 as the delayed domain crossing reset signal IOE_RSTD and the delayed internal clock iCLKD.

In an embodiment, in the domain crossing circuit 60, the first to fifth flip-flops 61-1 to 61-5 operating based on the system clock CLK and the first to fifth flip-flops 63-1 to 63-5 operating based on the data clock WCK are initialized according to the delayed domain crossing reset signal IOE_RST. The initialization operation of the flip-flops 61-1 to 61-5 and 63-1 to 63-5 includes determining a flip-flop outputting the first level by the delayed domain crossing reset signal iOE_RSTD input to the set terminal SET and the reset terminal RST.

In an embodiment, after the first to fifth flip-flops 61-1 to 61-5 operating based on the system clock CLK and the first to fifth flip-flops 63-1 to 63-5 operating based on the data clock WCK are all initialized by the delayed domain crossing reset signal iOE_RSTD, the first to fifth flip-flops 61-1 to 61-5 operating based on the system clock CLK start an operation of circulating the first level according to the delayed internal clock iCLKD, and at the end timing of the period B, the first to fifth flip-flops 63-1 to 63-5 operating based on the data clock WCK start an operation of circulating the first level according to a toggled data clock WCK. As described above, in order for the domain crossing circuit 60 to perform a normal operation, a pipe operation time (tD_pipe, for example, three cycles of the system clock CLK) is required so that the delayed internal clock iCLKD is received in the first to fifth flip-flops 61-1 to 61-5 based on the system clock CLK and then the delayed read/write command RW_CMDD is normally input to the first to fifth pipe circuits 62-1 to 62-5. In such a case, PIPE_IN_CMD of FIG. 4 indicates the timing at which the delayed read/write command RW_CMDD is input to and stored in the first to fourth pipe circuits 62-1 to 62-5.

However, when the data clock WCK is received in the domain crossing circuit 60 at the timing at which two cycles of the delayed internal clock iCLKD elapse after the delayed internal clock iCLKD is received in the first to fifth flip-flops 61-1 to 61-5 based on the system clock CLK, the domain crossing circuit 60 abnormally operates.

In an embodiment, the abnormal operation of the domain crossing circuit 60 is solved when the data clock WCK is received in the domain crossing circuit 60 at the timing at which three cycles of the delayed internal clock iCLKD elapse after the delayed internal clock iCLKD is received in the first to fifth flip-flops 61-1 to 61-5 based on the system clock CLK. That is, the period B in which the data clock WCK is fixed to a specific level needs to be extended by one cycle of the system clock CLK. An increase in the period B in which the data clock WCK is fixed to the specific level causes a decrease in the performance of the memory apparatus.

A memory apparatus in accordance with another embodiment of the present disclosure is configured so that the domain crossing circuit 60 normally operates without extending the period B in which the data clock WCK is fixed to a specific level.

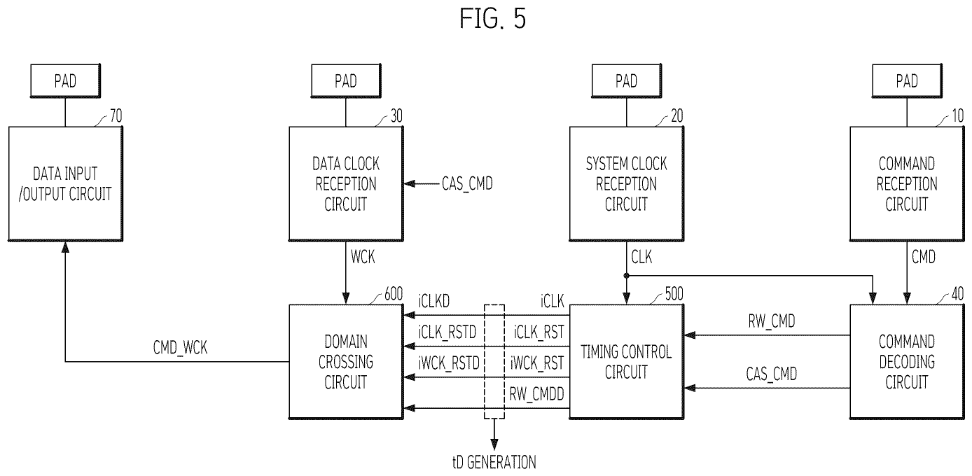

FIG. 5 is a diagram for describing the configuration of the memory apparatus in accordance with another embodiment of the present disclosure.

Referring to FIG. 5, the memory apparatus includes a command reception circuit 10, a system clock reception circuit 20, a data clock reception circuit 30, a command decoding circuit 40, a timing control circuit 500, a domain crossing circuit 600, and a data input/output circuit 70.

In an embodiment, the command reception circuit 10 receives a signal for controlling the operation of the memory apparatus from an external device (for example, a memory controller) through a pad PAD, and outputs the signal as a command signal CMD. The signal provided to the command reception circuit 10 from the external device is a single-ended signal or a differential-mode signal. The command signal CMD output from the command reception circuit 10 is provided to the command decoding circuit 40.

In an embodiment, the system clock reception circuit 20 receives, from the external device through a pad PAD, a signal for synchronizing the operation of the memory apparatus to the operation of the external device (for example, a memory controller), and outputs the signal as a system clock CLK. The signal provided to the system clock reception circuit 20 from the external device is a single-ended signal or a differential-mode signal. The system clock CLK output from the system clock reception circuit 20 is provided to the command decoding circuit 40 and the timing control circuit 500.

In an embodiment, the data clock reception circuit 30 is activated or deactivated based on a CAS command CAS_CMD. The activated data clock reception circuit 30 receives, from the external device through a pad PAD, a signal for synchronizing a data input/output timing of the memory apparatus to a data input/output timing of the external device (for example, a memory controller), and outputs the signal as a data clock WCK. The signal provided to the data clock reception circuit 30 from the external device is a single-ended signal or a differential-mode signal. The data clock CLK output from the data clock reception circuit 30 is provided to the domain crossing circuit 600.

In an embodiment, each of the command reception circuit 10, the system clock reception circuit 20, and the data clock reception circuit 30 includes a buffer.

In an embodiment, the command decoding circuit 40 receives the command signal CMD from the command reception circuit 10, and receives the system clock CLK from the system clock reception circuit 20. The command decoding circuit 40 decodes the command signal CMD in synchronization with the system clock CLK. The command decoding circuit 40 outputs a read/write command RW_CMD and the CAS command CAS_CMD as a decoding result. The command decoding circuit 40 also provides the read/write command RW_CMD and the CAS command CAS_CMD to the timing control circuit 500. The command decoding circuit 40 provides the CAS command CAS_CMD to the data clock reception circuit 30. The read/write command RW_CMD is a command generated when the external device instructs an operation (for example, a read operation) of the memory apparatus to output data stored in the memory apparatus or an operation (for example, a write operation) of the memory apparatus to store data transmitted to the memory apparatus. The CAS command CAS_CMD is a command generated when the external device instructs the activation of the data clock reception circuit 30.

In an embodiment, the timing control circuit 500 receives the system clock CLK from the system clock reception circuit 20 and receives the read/write command RW_CMD and the CAS command CAS_CMD from the command decoding circuit 40. The timing control circuit 500 delays each of the system clock CLK, the read/write command RW_CMD, and the CAS command CAS_CMD by a set delay time, and outputs the delayed clock and command. In such a case, the timing control circuit 500 may set the delay time by using one cycle of the system clock CLK as a unit delay time. For example, the timing control circuit 500 sets one cycle of the system clock CLK as a delay time, delays an input signal by the one cycle of the system clock CLK, and outputs the delayed signal. More specifically, for example, when the CAS command CAS_CMD is received from the command decoding circuit 40, the timing control circuit 500 delays the CAS command CAS_CMD by the one cycle of the system clock CLK and outputs the delayed command as a system domain reset signal iCLK_RST. In addition, when the one cycle of the system clock CLK elapses after the system domain reset signal iCLK_RST is output, the timing control circuit 500 outputs a data domain reset signal iWCK_RST. When the system clock CLK is received from the system clock reception circuit 20, the timing control circuit 500 outputs the system clock CLK as an internal clock iCLK after the delay time (one cycle of the system clock CLK). In such a case, the timing control circuit 500 outputs, as the internal clock iCLK, the system clock CLK at the timing at which the system domain reset signal iCLK_RST is output when the delay times of the system clock CLK and the CAS command CAS_CMD are the same. In some embodiments, the delay time of the read/write command RW_CMD is set in consideration of a latency, an asynchronous delay time inside the memory apparatus, an operation time of the domain crossing circuit 600, and the like. For example, when the latency is set so that stored data is output when 10 cycles of the system clock CLK elapse after a read command is received, the asynchronous delay time corresponds to one cycle of the system clock CLK, and the operation time of the domain crossing circuit 600 corresponds to three cycles of the system clock CLK, the memory apparatus sets the delay time of the read/write command RW_CMD to a time corresponding to six cycles of the system clock CLK. In such a case, when the read/write command RW_CMD is received from the command decoding circuit 40, the timing control circuit 500 delays the read/write command RW_CMD by six cycles of the system clock CLK and outputs the delayed command as a delayed read/write command RW_CMDD.

In addition, the internal clock iCLK, the delayed read/write command RW_CMDD, the system domain reset signal iCLK_RST, and the data domain reset signal iWCK_RST transmitted from the timing control circuit 500 to the domain crossing circuit 600 are further delayed by a time (for example, asynchronous delay time tD) transmitted from the timing control circuit 500 to the domain crossing circuit 600. Signals received in the domain crossing circuit 600, including the asynchronous delay time, are denoted as iCLKD, iCLK_RSTD, and iWCK_RSTD, and are described as a delayed internal clock iCLKD, a delayed system domain reset signal iCLK_RSTD, and a delayed data domain reset signal iWCK_RSTD, respectively.

In an embodiment, the domain crossing circuit 600 receives the data clock WCK from the data clock reception circuit 30, and receives the internal clock iCLK, the delayed read/write command RW_CMDD, the delayed system domain reset signal iCLK_RSTD, and the delayed data domain reset signal iWCK_RSTD transmitted from the timing control circuit 500.

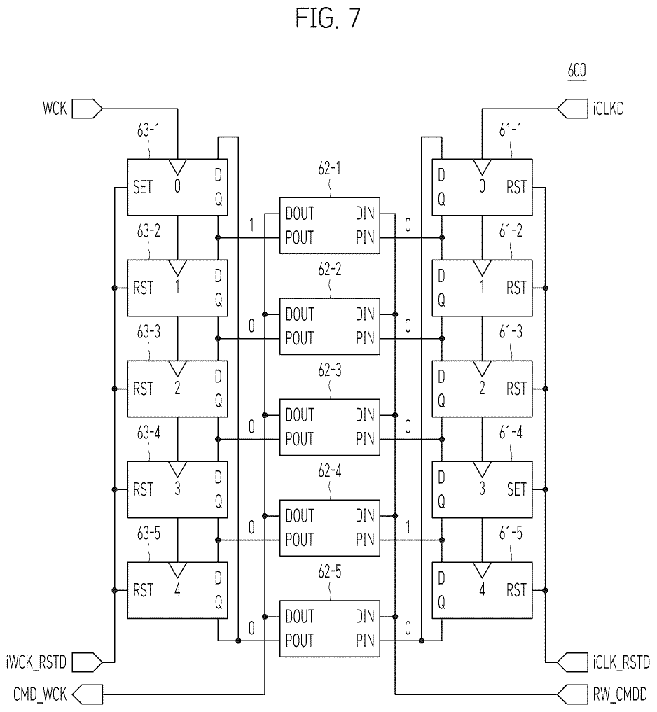

In an embodiment, the domain crossing circuit 600 converts a signal synchronized to the system clock CLK into a signal synchronized to the data clock WCK and outputs the converted signal. Accordingly, the domain crossing circuit 600 converts the delayed read/write command RW_CMDD synchronized to the system clock WCK into a data input/output command CMD_WCK synchronized to the data clock WCK and outputs the data input/output command CMD_WCK under the control of the data clock WCK, the internal clock iCLK based on the system clock WCK, the system domain reset signal iCLK_RST, and the data domain reset signal iWCK_RST. The operation of the domain crossing circuit 600 is described in detail with reference to FIG. 7.

In an embodiment, the data input/output circuit 70 is activated when the data input/output command CMD_WCK is received, and outputs data to the external device or receives data from the external device through the pad PAD.

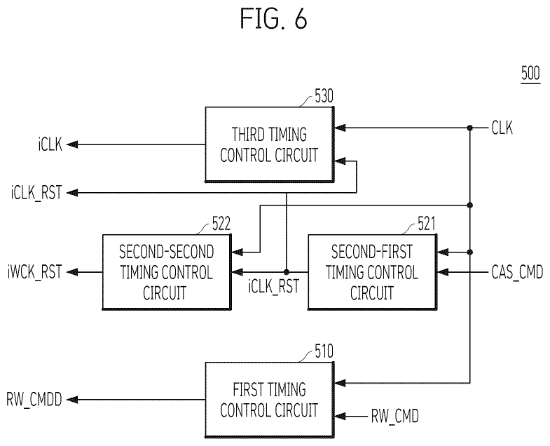

FIG. 6 is a diagram for describing the configuration of the timing control circuit 500 included in the memory apparatus in accordance with another embodiment of the present disclosure.

Referring to FIG. 6, the timing control circuit 500 includes a plurality of timing control circuits 510, 521, 522, and 530. For example, the timing control circuit 500 includes a first timing control circuit 510, a second-first timing control circuit 521, a second-second timing control circuit 522, and a third timing control circuit 530 so as to set output timings of the internal clock iCLK, the system domain reset signal iCLK_RST, the data domain reset signal iWCK_RST, and the delayed read/write command RW_CMDD by delaying the read/write command RW_CMD, the CAS command CAS_CMD, and the system clock CLK by set delay times, respectively.

In an embodiment, the first timing control circuit 510 receives the read/write command RW_CMD and the system clock CLK and outputs the delayed read/write command RW_CMDD. For example, the first timing control circuit 510 delays the read/write command RW_CMD by a set delay time (for example, six cycles of the system clock CLK), and outputs the delayed command as the delayed read/write command RW_CMDD. That is, the first timing control circuit 510 outputs the delayed read/write command RW_CMDD at the timing at which the six cycles of the system clock CLK elapse from the timing at which the read/write command RW_CMD is received.

In an embodiment, the second-first timing control circuit 521 receives the CAS command CAS_CMD and the system clock CLK and outputs the system domain reset signal iCLK_RST. For example, the second-first timing control circuit 521 delays the CAS command CAS_CMD by a set delay time (for example, one cycle of the system clock CLK) and outputs the delayed command as the system domain reset signal iCLK_RST. That is, the second-first timing control circuit 521 outputs the system domain reset signal iCLK_RST at the timing at which the one cycle of the system clock CLK elapses from the timing at which the CAS command CAS_CMD is received.

In an embodiment, the second-second timing control circuit 522 receives the system domain reset signal iCLK_RST and the system clock CLK and outputs the data domain reset signal iWCK_RST. For example, the second-second timing control circuit 522 delays the system domain reset signal iCLK_RST by a set delay time (for example, one cycle of the system clock CLK) and outputs the delayed signal as the data domain reset signal iWCK_RST. That is, the second-second timing control circuit 522 outputs the data domain reset signal iWCK_RST at the timing at which the one cycle of the system clock CLK elapses from the timing at which the system domain reset signal iCLK_RST is received.

In an embodiment, the third timing control circuit 530 receives the system clock CLK and the system domain reset signal iCLK_RST and outputs the internal clock iCLK. The third timing control circuit 530 may output the system clock CLK as the internal clock iCLK when the system domain reset signal iCLK_RST is output. Accordingly, the third timing control circuit 530 outputs the system clock CLK as the internal clock iCLK when a set delay time (for example, one cycle of the system clock CLK) elapses after the CAS command CAS_CMD is received. That is, the third timing control circuit 530 outputs the system clock CLK as the internal clock iCLK at the timing at which the one cycle of the system clock CLK elapses from the timing at which the CAS command CAS_CMD is received.

Each of the first timing control circuit 510, the second-first timing control circuit 521, the second-second timing control circuit 522, and the third timing control circuit 530 includes a shift register in which a plurality of flip-flops are connected in series. Unlike the first timing control circuit 510, the second-first timing control circuit 521, and the second-second timing control circuit 522, the third timing control circuit 530 includes a flip-flop and an AND gate. The flip-flop may output a high-level signal when the system domain reset signal iCLK_RST is received. The AND gate may receive the output of the flip-flop and the system clock CLK and perform an AND operation on the received signal and clock.

FIG. 7 is a diagram for describing the configuration of the domain crossing circuit 600 included in the memory apparatus in accordance with another embodiment of the present disclosure.

Referring to FIG. 7, the domain crossing circuit 600 includes first to fifth flip-flops 61-1 to 61-5 operating based on the system clock CLK, first to fifth pipe circuits 62-1 to 62-5, and first to fifth flip-flops 63-1 to 63-5 operating based on the data clock WCK.

In an embodiment, each of the first to fifth flip-flops 61-1 to 61-5 operating based on the system clock CLK receives the delayed internal clock iCLKD. In addition, an input/output structure of the first to fifth flip-flops 61-1 to 61-5 operating based on the system clock CLK is a ring structure. For example, an output of the first flip-flop 61-1 is provided as an input of the second flip-flop 61-2, an output of the second flip-flop 61-2 is provided as an input of the third flip-flop 61-3, an output of the third flip-flop 61-3 is provided as an input of the fourth flip-flop 61-4, an output of the fourth flip-flop 61-4 is provided as an input of the fifth flip-flop 61-5, and an output of the fifth flip-flop 61-5 is provided as an input of the first flip-flop 61-1. In addition, one of the first to fifth flip-flops 61-1 to 61-5 receives the delayed system domain reset signal iCLK_RSTD through a set terminal SET thereof, and the remaining flip-flops receive the delayed system domain reset signal iCLK_RSTD through reset terminals RST thereof. In FIG. 7, among the first to fifth flip-flops 61-1 to 61-5, the fourth flip-flop 61-4 receives the delayed system domain reset signal iCLK_RSTD through the set terminal SET thereof, and the remaining flip-flops 61-1, 61-2, 61-3, and 61-5 receive the delayed system domain reset signal iCLK_RSTD through the reset terminals RST thereof. When the delayed system domain reset signal iCLK_RSTD is received in the first to fifth flip-flops 61-1 to 61-5, the fourth flip-flop 61-4 outputs a signal at a first level (for example, high level of 1), and the remaining flip-flops 61-1, 61-2, 61-3, and 61-5 output a signal at a second level (for example, low level of 0).

In an embodiment, the first to fifth flip-flops 61-1 to 61-5 configured in this manner and operating based on the system clock CLK provide the output of a previous flip-flop as the input of a next flip-flop whenever the delayed internal clock iCLKD transitions to a specific level.

For example, whenever the delayed internal clock iCLKD transitions to the specific level, the output of the fourth flip-flop 61-4, which is at the first level, is provided as the input of the fifth flip-flop 61-5, the output of the fifth flip-flop 61-5 is provided as the input of the first flip-flop 61-1, the output of the first flip-flop 61-1 is provided as the input of the second flip-flop 61-2, the output of the second flip-flop 61-2 is provided as the input of the third flip-flop 61-3, and the output of the third flip-flop 61-3 is provided again as the input to the fourth flip-flop 61-4. In such a case, each of the first to fifth flip-flops 61-1 to 61-5 may store the level of a signal input at the timing at which the delayed internal clock iCLKD transitions to the specific level, and may output the stored signal. Accordingly, whenever the delayed internal clock iCLKD transitions to the specific level, each of the outputs of the first to fifth flip-flops 61-1 to 61-5 operating based on the system clock CLK is output by circulating the first level being the output of the fourth flip-flop 61-4.

In an embodiment, each of the first to fifth pipe circuits 62-1 to 62-5 receives the delayed read/write command RW_CMDD through an input terminal DIN thereof. In addition, the first to fifth pipe circuits 62-1 to 62-5 receive the outputs of the first to fifth flip-flops 61-1 to 61-5 operating based on the system clock CLK through input control terminals PIN thereof, respectively. For example, the input control terminal PIN of the first pipe circuit 62-1 receives the output of the first flip-flop 61-1. The input control terminal PIN of the second pipe circuit 62-2 receives the output of the second flip-flop 61-2. The input control terminal PIN of the third pipe circuit 62-3 receives the output of the third flip-flop 61-3. The input control terminal PIN of the fourth pipe circuit 62-4 receives the output of the fourth flip-flop 61-4. The input control terminal PIN of the fifth pipe circuit 62-5 receives the output of the fifth flip-flop 61-5.

In an embodiment, when a signal of the first level (e.g., 1) is received through the input control terminal PIN, each of the first to fifth pipe circuits 62-1 to 62-5 configured in this manner receives and stores the delayed read/write command RW_CMDD provided to the input terminal DIN.

For example, whenever the delayed internal clock iCLKD transitions to the specific level, the output of each of the first to fifth flip-flops 61-1 to 61-5 operating based on the system clock CLK circulates the first level being the output of the fourth flip-flop 61-4. The outputs of the first to fifth flip-flops 61-1 to 61-5 are provided to the input control terminals PINs of the first to fifth pipe circuits 62-1 to 62-5, respectively. Therefore, the first level circulating along the first to fifth flip-flops 61-1 to 61-5 is controlled so that only one of the first to fifth pipe circuits 62-1 to 62-5 receives and stores the delayed read/write command RW_CMDD. In addition, a pipe circuit that receives and stores the delayed read/write command RW_CMDD is also circulated in the order of the fourth pipe circuit 62-4, the fifth pipe circuit 62-5, the first pipe circuit 62-1, the second pipe circuit 62-2, and the third pipe circuit 62-3.

In an embodiment, each of the first to fifth flip-flops 63-1 to 63-5 operating based on the data clock WCK receives the delayed data clock WCK. In addition, the input/output structure of the first to fifth flip-flops 63-1 to 63-5 operating based on the data clock CLK is a ring structure. For example, an output of the first flip-flop 63-1 is provided as an input of the second flip-flop 63-2, an output of the second flip-flop 63-2 is provided as an input of the third flip-flop 63-3, an output of the third flip-flop 63-3 is provided as an input of the fourth flip-flop 63-4, an output of the fourth flip-flop 63-4 is provided as an input of the fifth flip-flop 63-5, and an output of the fifth flip-flop 63-5 is provided as an input of the first flip-flop 63-1. One of the first to fifth flip-flops 63-1 to 63-5 receives the delayed data domain reset signal iWCK_RSTD through a set terminal SET thereof, and the remaining flip-flops receive the delayed data domain reset signal iWCK_RSTD through a reset terminal RST thereof. In FIG. 7, among the first to fifth flip-flops 63-1 to 63-5, the first flip-flop 63-1 receives the delayed data domain reset signal iWCK_RSTD through the set terminal SET thereof, and the remaining flip-flops 63-2, 63-3, 63-4, and 63-5 receive the delayed data domain reset signal iWCK_RSTD through the reset terminals RST thereof. When the delayed data domain reset signal iWCK_RSTD is received in the first to fifth flip-flops 63-1 to 63-5, the first flip-flop 63-1 outputs a signal at the first level (for example, high level of 1), and the remaining flip-flops 63-2, 63-3, 63-4, and 63-5 output a signal at the second level (for example, low level of 0).

In an embodiment, the first to fifth flip-flops 63-1 to 63-5 configured in this manner and operating based on the data clock CLK provide the output of a previous flip-flop as the input of a next flip-flop whenever the data clock WCK transitions to a specific level. For example, whenever the data clock WCK transitions to the specific level, the output of the first flip-flop 63-1, which is at the first level, is provided as the input of the second flip-flop 63-2, the output of the second flip-flop 63-2 is provided as the input of the third flip-flop 63-3, the output of the third flip-flop 63-3 is provided as the input of the fourth flip-flop 63-4, the output of the fourth flip-flop 63-4 is provided as the input of the fifth flip-flop 63-5, and the output of the fifth flip-flop 63-5 is provided again as the input of the first flip-flop 63-1. In such a case, each of the first to fifth flip-flops 63-1 to 63-5 is configured to store the level of a signal input when the data clock WCK transitions to the specific level, and to output the stored signal. Accordingly, whenever the data clock WCK transitions to the specific level, each of the outputs of the first to fifth flip-flops 63-1 to 63-5 circulates and outputs the first level being the output of the first flip-flop 63-1.

In an embodiment, the first to fifth pipe circuits 62-1 to 62-5 receive the outputs of the first to fifth flip-flops 63-1 to 63-5 operating based on the data clock WCK through output control terminals POUT thereof. In addition, output terminals DOUT of the first to fifth pipe circuits 62-1 to 62-5 are commonly connected, and the data input/output command CMD_WCK is output from a node to which the output terminals DOUT are commonly connected.

For example, the output control terminal POUT of the first pipe circuit 62-1 receives the output of the first flip-flop 63-1. The output control terminal POUT of the second pipe circuit 62-2 receives the output of the second flip-flop 63-2. The output control terminal POUT of the third pipe circuit 62-3 receives the output of the third flip-flop 63-3. The output control terminal POUT of the fourth pipe circuit 62-4 receives the output of the fourth flip-flop 63-4. The output control terminal POUT of the fifth pipe circuit 62-5 receives the output of the fifth flip-flop 63-5.

Accordingly, when a signal of the first level (e.g., 1) is received through the output control terminal POUT, each of the first to fifth pipe circuits 62-1 to 62-5 outputs the data input/output command CMD_WCK to the output terminal DOUT.

The operations of the first to fifth flip-flops 63-1 to 63-5 operating based on the data clock WCK and the first to fifth pipe circuits 62-1 to 62-5 are described as follows.

In an embodiment, each of the outputs of the first to fifth flip-flops 63-1 to 63-5 operating whenever the data clock WCK transitions to the specific level circulates the first level being the output of the first flip-flop 63-1. Accordingly, the first level circulating along the first to fifth flip-flops 63-1 to 63-5 is controlled so that only one of the first to fifth pipe circuits 62-1 to 62-5 outputs the data input/output command CMD_WCK. In addition, a pipe circuit that outputs the data input/output command CMD_WCK is also circulated in the order of the first pipe circuit 62-1, the second pipe circuit 62-2, the third pipe circuit 62-3, the fourth pipe circuit 62-4, and the fifth pipe circuit 62-5.

In an embodiment, in a case in which the delayed system domain reset signal iCLK_RSTD is input to the set terminal SET of the fourth flip-flop 61-4 among the first to fifth flip-flops 61-1 to 61-5 based on the system clock CLK and the delayed data domain reset signal iWCK_RSTD is input to the set terminal SET of the first flip-flop 63-1 among the first to fifth flip-flops 63-1 to 63-5 based on the data clock WCK, when three cycles of the data clock WCK elapse from the timing at which the delayed read/write command RW_CMDD is stored in one of the first to fifth pipe circuits 62-1 to 62-5, the domain crossing circuit 60 configured in this manner outputs the data input/output command CMD_WCK. In addition, in order for the domain crossing circuit 60 to operate normally, a pipe operation time (tD_pipe, for example, three cycles of the system clock CLK) is required to allow the delayed read/write command RW_CMDD to be normally input to the first to fifth pipe circuits 62-1 to 62-5 after the delayed internal clock iCLKD is received in the first to fifth flip-flops 61-1 to 61-5 based on the system clock CLK.

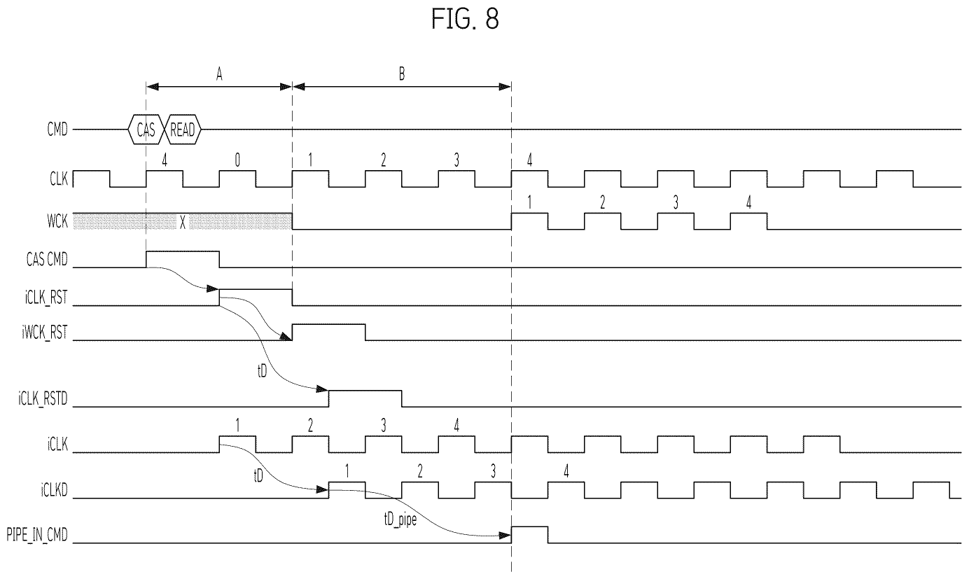

FIG. 8 is a timing diagram for describing the operation of the memory apparatus in accordance with another embodiment of the present disclosure.

Referring to FIG. 8, a signal for controlling the read operation of the memory apparatus is received in the memory apparatus from the external device. The signal for controlling the read operation includes a signal CAS for generating the CAS command CAS_CMD and a signal for generating the read/write command RW_CMD.

In an embodiment, the command decoding circuit 40 decodes signals provided from the command reception circuit 10 and generates the CAS command CAS_CMD and the read/write command RW_CMD. The CAS command CAS_CMD activates the data clock reception circuit 30. A line transmitting the data clock WCK is maintained in a floating state X from the timing at which the CAS command CAS_CMD is generated to the timing at which two cycles of the system clock CLK elapse. Subsequently, the data clock WCK is fixed to a set level (for example, a low level) until three cycles of the system clock CLK elapse. The data clock WCK is toggled after the three cycles of the system clock CLK elapse. For the convenience of description, a period where the line transmitting the data clock WCK is floated is called period A, and a period where the data clock WCK is fixed to the set level is called period B. The above description may be the same as the description of FIG. 4.

In an embodiment, the timing control circuit 500 generates the system domain reset signal iCLK_RST by delaying the CAS command CAS_CMD by one cycle of the system clock CLK. In addition, the timing control circuit 500 outputs the system clock CLK as the internal clock iCLK when the system domain reset signal iCLK_RST is generated. Accordingly, the generation timing of the system domain reset signal iCLK_RST and the generation timing of the internal clock iCLK are the same. In addition, the timing control circuit 500 generates the data domain reset signal iWCK_RST by delaying the system domain reset signal iCLK_RST by the one cycle of the system clock CLK.

In an embodiment, the system domain reset signal iCLK_RST, the internal clock iCLK, and the data domain reset signal iWCK_RST are delayed by the asynchronous delay time tD corresponding to loading according to the distance between the timing control circuit 500 and the domain crossing circuit 600, and are received in the domain crossing circuit 600 as the delayed system domain reset signal iCLK_RSTD, the delayed data domain reset signal iWCK_RSTD, and the delayed internal clock iCLKD.

In an embodiment, in the domain crossing circuit 600, the first to fifth flip-flops 61-1 to 61-5 operating based on the system clock CLK are initialized according to the delayed system domain reset signal iCLK_RSTD, and the first to fifth flip-flops 63-1 to 63-5 operating based on the data clock WCK are initialized according to the delayed data domain reset signal iWCK_RSTD. The initialization operation of the flip-flops 61-1 to 61-5 and 63-1 to 63-5 includes determining a flip-flop outputting the first level by the delayed system domain reset signal iCLK_RSTD and the delayed data domain reset signal iWCK_RSTD input to the set terminal SET and the reset terminal RST.

In an embodiment, after the first to fifth flip-flops 61-1 to 61-5 operating based on the system clock CLK and the first to fifth flip-flops 63-1 to 63-5 operating based on the data clock WCK are all initialized by the delayed system domain reset signal iCLK_RSTD and the delayed data domain reset signal iWCK_RSTD, the first to fifth flip-flops 61-1 to 61-5 operating based on the system clock CLK start an operation of circulating the first level according to the delayed internal clock iCLKD, and at the end timing of the period B, the first to fifth flip-flops 63-1 to 63-5 operating based on the data clock WCK start an operation of circulating the first level according to a toggled data clock WCK. As described above, in order for the domain crossing circuit 600 to perform a normal operation, a pipe operation time (tD_pipe, for example, three cycles of the system clock CLK) is required so that the delayed internal clock iCLKD is received in the first to fifth flip-flops 61-1 to 61-5 based on the system clock CLK and then the delayed read/write command RW_CMDD is normally input to the first to fifth pipe circuits 62-1 to 62-5. In such a case, PIPE_IN_CMD of FIG. 8 indicates the timing at which the delayed read/write command RW_CMDD is input to and stored in the first to fourth pipe circuits 62-1 to 62-5.

In an embodiment, the internal clock iCLK of FIG. 8 is generated at an earlier timing by one cycle of the system clock CLK compared to the internal clock iCLK of FIG. 4. Accordingly, the timing at which the internal clock iCLK is transmitted to the domain crossing circuit 600 is also earlier by one cycle of the system clock CLK. That is, the timing control circuit 500 outputs the internal clock iCLK even in a period where a line transmitting the data clock WCK from the external device to the memory apparatus is floated.

As a result, the delayed internal clock iCLKD transmitted to the domain crossing circuit 600 is transmitted at an earlier timing by one cycle of the system clock CLK compared to the delayed internal clock iCLKD illustrated in FIG. 4.

Accordingly, in the domain crossing circuit 600, the delayed internal clock iCLKD is received in the first to fifth flip-flops 61-1 to 61-5 based on the system clock CLK, and the data clock WCK is received at the time point at which three cycles of the system clock CLK elapse.

Because the data clock WCK is received at the time point at which three cycles of the system clock CLK elapse after the delayed internal clock iCLKD is received, the domain crossing circuit 600 can secure the pipe operation time tD_pipe and operate normally.

The memory apparatus in accordance with another embodiment of the present disclosure can secure the pipe operation time tD_pipe of the domain crossing circuit 600 regardless of a change in the period B in which the data clock WCK is fixed to a specific level.

Although embodiments according to the technical idea of the present disclosure have been described above with reference to the accompanying drawings, this is only for describing the embodiments according to the concept of the present disclosure, and the present disclosure is not limited to the above embodiments. Various types of substitutions, modifications, and changes for the embodiments may be made by those skilled in the art, to which the present disclosure pertains, without departing from the technical idea of the present disclosure defined in the following claims, and it should be construed that these substitutions, modifications, and changes belong to the scope of the present disclosure. Furthermore, the embodiments may be combined to form additional embodiments.

What is claimed is:

1. A memory apparatus comprising:
a timing control circuit configured to output a system domain reset signal and a data domain reset signal based on a system clock, and output the system clock as an internal clock when the system domain reset signal is output, an output timing of the system domain reset signal being different from an output timing of the data domain reset signal; and
a domain crossing circuit comprising a plurality of first flip-flops operating based on the internal clock, and a plurality of second flip-flops coupled to the plurality of first flip-flops and operating based on a data clock, the plurality of first flip-flops being initialized by the system domain reset signal, the plurality of second flip-flops being initialized by the data domain reset signal.

2. The memory apparatus of claim 1, wherein the domain crossing circuit requires a pipe operation time from a time that the internal clock is received to a time that the data clock is received.

3. The memory apparatus of claim 2, wherein, in the timing control circuit, the output timing of the system domain reset signal is earlier than the output timing of the data domain reset signal.

4. The memory apparatus of claim 3, wherein, in the timing control circuit, the output timing of the system domain reset signal is earlier than a toggling timing of the data clock by the pipe operation time.

5. The memory apparatus of claim 4, wherein the timing control circuit is configured to generate the data domain reset signal by delaying the system domain reset signal.

6. The memory apparatus of claim 5, wherein the timing control circuit is configured to generate the system domain reset signal by delaying a CAS command by a first set period of the system clock, and
generate the data domain reset signal by delaying the system domain reset signal by a second set period of the system clock different from the first set period of the system clock.

7. The memory apparatus of claim 1, wherein the domain crossing circuit further comprises:
a plurality of pipe circuits configured to convert a first command based on the system clock into a second command based on the data clock which is based on outputs of the plurality of first flip-flops and the plurality of second flip-flops.

8. The memory apparatus of claim 7, wherein the system domain reset signal is input to a first terminal of one of the plurality of first flip-flops, and
the system domain reset signal is input to second terminals of remaining flip-flops of the plurality of first flip-flops.

9. The memory apparatus of claim 8, wherein the data domain reset signal is input to a first terminal of one of the plurality of second flip-flops, and
the data domain reset signal is input to second terminals of remaining flip-flops of the plurality of second flip-flops.

10. The memory apparatus of claim 9, wherein initialization of the plurality of first flip-flops and initialization of the plurality of second flip-flops are such that the flip-flop receiving the system domain reset signal or the data domain reset signal through the first terminal outputs a level different from levels of the remaining flip-flops.

11. The memory apparatus of claim 10, wherein input and output structures of the plurality of first flip-flops and the plurality of second flip-flops are ring structures.

12. A memory apparatus comprising:
a command decoding circuit configured to output a read and write (read/write) command and a column address strobe (CAS) command synchronized to a system clock;
a timing control circuit configured to output a system domain reset signal, a data domain reset signal, and an internal clock based on the CAS command and the system clock, and output a delayed read/write command based on the system clock and the read/write command; and
a domain crossing circuit configured to synchronize the delayed read/write command with a data clock and output a data input and output (input/output) command under control of the system domain reset signal, the data domain reset signal, and the internal clock.

13. The memory apparatus of claim 12, wherein the timing control circuit is further configured to output the system domain reset signal at a timing earlier than an output timing of the data domain reset signal.

14. The memory apparatus of claim 13, wherein the timing control circuit is further configured to output the system domain reset signal based on the CAS command and the system clock, output the system clock as the internal clock when the system domain reset signal is output, and output, as the data domain reset signal, the delayed system domain reset signal generated by delaying the system domain reset signal.

15. The memory apparatus of claim 14, wherein, in the domain crossing circuit, a reception timing of the internal clock is earlier than a reception timing of the data clock.

16. The memory apparatus of claim 15, wherein the domain crossing circuit is further configured to toggle the data clock after the internal clock is received and a pipe operation time elapses.
